(19) United States
(12) Patent Application Publication
(10) Pub. No.: US 2023/0253288 A1
(43) Pub. Date: Aug. 10, 2023

(54) IMMERSION COOLING FOR INTEGRATED CIRCUIT DEVICES

(71) Applicant: Intel Corporation, Santa Clara, CA (US)

(72) Inventors: Abdulafeez Adebiyi, Chandler, AZ (US); Je-Young Chang, Tempe, AZ (US); Devdatta Kulkarni, Portland, OR (US); Sandeep Ahuja, Portland, OR (US)

(73) Assignee: Intel Corporation, Santa Clara, CA (US)

(21) Appl. No.: 17/668,236

(22) Filed: Feb. 9, 2022

(51) Int. Cl. H01L 23/373; H01L 23/427; H01L 25/065; H01L 21/48; H01L 21/56; H01L 23/29

(52) U.S. Cl. CPC H01L 23/3733; H01L 23/427; H01L 25/0655; H01L 21/4871; H01L 21/56; H01L 23/291; H01L 23/29; H01L 23/3732; H01L 24/13

(57) ABSTRACT

An integrated circuit device may include an integrated circuit die coupled to a substrate, and a porous material on the die or a thermal interface material and extending beyond the edges of the die and over the substrate. An integrated circuit system may include a substrate with a power supply and an integrated circuit die, such that a porous material on the die extends over the substrate beyond a footprint of the die. A porous material may be formed on and beyond an edge of a received integrated circuit die coupled to a substrate or a thermal interface material on the die.

### BACKGROUND

The integrated circuit industry is continually striving to produce ever faster, smaller, and thinner integrated circuit devices and packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. Thus, heat dissipation devices are used to remove heat from the integrated circuit devices in an integrated circuit package. In one example, heat spreading and dissipation devices may be thermally attached to integrated circuit devices for heat removal. The heat spreading and dissipation devices, in turn, dissipate the heat into the surrounding atmosphere. In another example, a liquid cooling device, such as a heat exchanger or a heat pipe, may be thermally attached to integrated circuit devices for heat removal. However, as power densities and power envelopes increase to reach peak performance, these methods are becoming ineffective in removing sufficient amounts of heat.

One emerging heat removal technique is two-phase immersion cooling. This technique includes immersing an integrated circuit assembly into a liquid cooling bath containing a low boiling point liquid which vaporizes and, thus, cools the integrated circuit assembly through latent heat transfer, as it generates heat. Although it is a promising technology, two-phase immersion cooling has various challenges to effective operation, as will be understood to those skilled in the art.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a cross-section view of an example two-phase immersion cooling system, including a porous material thermally coupled to an integrated circuit die, arranged in accordance with at least some implementations of the present disclosure.

FIG. 2 illustrates a cross-section view of an example integrated circuit package, including porous material thermally coupled to and encapsulating multiple integrated circuit dice, arranged in accordance with at least some implementations of the present disclosure.

FIG. 3 shows a cross-section view of another example of an integrated circuit package, where porous material is thermally coupled to multiple integrated circuit dice and attached to package substrate via a frame, arranged in accordance with at least some implementations of the present disclosure.

FIG. 4 illustrates a cross-section view of an example of an integrated circuit package having porous material on a thermal interface material and encapsulating integrated circuit dice, arranged in accordance with at least some implementations of the present disclosure.

FIG. 5 illustrates a cross-section view of an example of an integrated circuit package having porous material directly on and encapsulating integrated circuit dice, arranged in accordance with at least some implementations of the present disclosure.

FIG. 6 illustrates a cross-section view of an example integrated circuit package, including porous material thermally coupled to integrated circuit dice using spreader inserts, arranged in accordance with at least some implementations of the present disclosure.

FIG. 7 shows a cross-section view of another example of an integrated circuit package, where porous material is thermally coupled to integrated circuit dice via spreader inserts, and mechanically coupled to package substrate via frames, arranged in accordance with at least some implementations of the present disclosure.

FIG. 8 illustrates a cross-section view of another example of an integrated circuit package where porous material is coupled to integrated circuit dice by forming porous material on and over a package substrate, beyond thermal interface material, spreader inserts, and a second surface of integrated circuit dice, arranged in accordance with at least some implementations of the present disclosure.

FIG. 9 illustrates a cross-section view of another example of an integrated circuit package where porous material is coupled to integrated circuit dice by forming porous material on spreader inserts absent a thermal interface material, arranged in accordance with at least some implementations of the present disclosure.

FIG. 10 shows a two-phase immersion cooling system with a fluid containment structure, a dielectric low-boiling point liquid disposed within the fluid containment structure, and a condensation structure at least partially within the fluid containment structure, arranged in accordance with at least some implementations of the present disclosure.

FIG. 11 illustrates various processes or methods for forming porous material on a received integrated circuit die, arranged in accordance with at least some implementations of the present disclosure.

FIG. 12 illustrates an electronic or computing device/system in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer of a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side,” if used herein, generally refers to the side of the substrate of the integrated circuit package closest to the plane of attachment to a printed circuit board, motherboard, or other package. This is in contrast to the term “die side,” which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “ceramic” generally refers to non-metallic, non-organic materials, e.g., particles for cold-spray deposition, and can include diamond.

Here, the term “bond pad” generally refers to metallization structures that terminate integrated traces and vias in integrated circuit packages and dice. The term “solder pad” may be occasionally substituted for “bond pad” and carries the same meaning.

Here, the term “solder bump” generally refers to a solder layer formed on a bond pad. The solder layer typically has a round shape, hence the term “solder bump.”

Here, the term “sidewall” or “edge” when describing an integrated circuit die generally refers to the surfaces of the die with the smallest dimension, which are also generally the surfaces neither coupled to a substrate nor opposite the substrate. These surfaces can generally be thought of as forming the perimeter of the die relative to other objects on or regions of a substrate.

Here, the term “substrate” generally refers to a planar platform including dielectric and metallization structures. The substrate mechanically supports and electrically couples one or more integrated circuit dice on a single platform, with encapsulation of the one or more integrated circuit dice by a moldable dielectric material. The substrate may be an interposer.

The substrate generally includes solder bumps as bonding interconnects on both sides. One side of the substrate, generally referred to as the “die side,” includes solder bumps for chip or die bonding. The opposite side of the substrate, generally referred to as the “land side,” includes copper pads for socketing or solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top,” “bottom,” “above,” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to the use of porous materials to enhance boiling and otherwise improve heat transfer from integrated circuit devices. The porous materials need not be metallic, but are generally preferred to be thermally conductive. In some embodiments, an integrated circuit package includes an integrated circuit die coupled to a substrate, and a porous material on the die, or a thermal interface material on the die, and extending beyond one or more sidewalls or edges of the die and further over the substrate. In some embodiments, an integrated circuit system includes a substrate with a power supply and an integrated circuit die, as well as a porous material on the die that extends over the substrate beyond a footprint of the die. In some embodiments, one or more integrated circuit dice may be coupled to a substrate and a porous material may be formed on and beyond the one or more integrated circuit dice over the substrate.

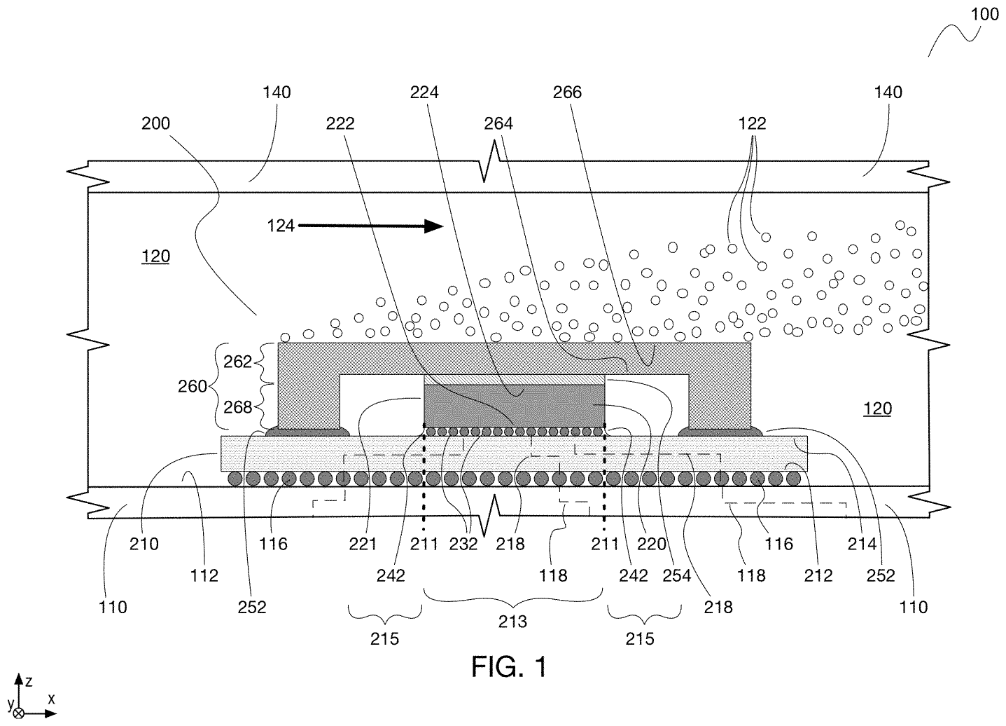

FIG. 1 illustrates a cross-section view of an example two-phase immersion cooling system 100 including a porous material 260 thermally coupled to an integrated circuit die 220, arranged in accordance with at least some implementations of the present disclosure. As shown, two-phase immersion cooling system 100 has at least one integrated circuit package 200 electrically attached to an electronic substrate 110. Electronic substrate 110 may be any appropriate structure, including, but not limited to, a motherboard, printed circuit board, and the like. Electronic substrate 110 may include a plurality of dielectric material layers (not shown), which may include build-up films and/or solder resist layers, and may be composed of an appropriate dielectric material, including, but not limited to, polyethylene terephthalate (PET) support film, bismaleimide triazine resin, fire retardant grade 4 material, polyimide material, silica filled epoxy material, ceramic material, silicon dioxide, or glass, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

Electronic substrate 110 may further include conductive routes 118 or “metallization” (shown in dashed lines) extending through electronic substrate 110. As will be understood to those skilled in the art, conductive routes 118 may be a combination of conductive traces (not shown) and conductive vias (not shown) extending through the plurality of dielectric material layers (not shown). These conductive traces and conductive vias are well known in the art and, for purposes of clarity, are not shown in FIG. 1. The conductive traces and the conductive vias may be made of any appropriate conductive material, including but not limited to, metals, such as copper, silver, nickel, gold, and aluminum, alloys thereof, and the like. As will be understood to those skilled in the art, electronic substrate 110 may be a cored substrate or a coreless substrate.

Integrated circuit package 200 may be electrically attached to electronic substrate 110 in a configuration generally known as a flip-chip or controlled collapse chip connection (“C4”) configuration, according to some embodiments. Integrated circuit package 200 may include a package substrate 210 with a first surface 212 and an opposing second surface 214, and an integrated circuit die 220 electrically attached proximate second surface 214 of package substrate 210. In some embodiments, package substrate 210 is an interposer attached to electronic substrate 110 with the plurality of package-to-substrate interconnects 116. In some embodiments, package-to-substrate interconnects 116 extends between bond pads (not shown) proximate a first surface 112 of electronic substrate 110 and bond pads (not shown) proximate first surface 212 of package substrate 210.

Package substrate 210 may include any of the materials and/or structure as discussed previously with regard to electronic substrate 110. Package substrate 210 may further include conductive routes 218 or “metallization” (shown in dashed lines) extending through package substrate 210, which may include any of the materials and/or structures as discussed previously with regard to conductive routes 118 of electronic substrate 110. The bond pads (not shown) proximate first surface 212 of package substrate 210 may be in electrical contact with conductive routes 218, and conductive routes 218 may extend through package substrate 210 and be electrically connected to bond pads (not shown) proximate second surface 214 of package substrate 210. As will be understood to those skilled in the art, package substrate 210 may be a cored substrate or a coreless substrate.

Integrated circuit die 220 may be any appropriate device, including, but not limited to, a microprocessor, a chipset, a graphics device, a wireless device, a memory device, an application specific integrated circuit, a transceiver device, an input/output device, combinations thereof, stacks thereof, or the like. As shown in FIG. 1, integrated circuit die 220 may have a first surface 222 and an opposing second surface 224.

In some embodiments, integrated circuit die 220 electrically attaches to package substrate 210 with a plurality of die-to-substrate interconnects 232. In some embodiments, die-to-substrate interconnects 232 extend between bond pads (not shown) on first surface 212 of package substrate 210 and bond pads (not shown) on first surface 222 of integrated circuit die 220. Die-to-substrate interconnects 232 may be any appropriate electrically conductive material or structure, including, but not limited to, solder balls, metal bumps or pillars, metal filled epoxies, or a combination thereof. In some embodiments, die-to-substrate interconnects 232 are solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In some embodiments, die-to-substrate interconnects 232 are copper bumps or pillars. In some embodiments, die-to-substrate interconnects 232 are metal bumps or pillars coated with a solder material.

Die-to-substrate interconnects 232 may be in electrical communication with integrated circuitry (not shown) within integrated circuit die 220 and may be in electrical contact with conductive routes 218. Conductive routes 218 may extend through package substrate 210 and be electrically connected to package-to-substrate interconnects 116. As will be understood to those skilled in the art, package substrate 210 may be an interposer and reroute a fine pitch (center-to-center distance) of die-to-substrate interconnects 232 to a relatively wider pitch of package-to-substrate interconnects 116. Package-to-substrate interconnects 116 may be any appropriate electrically conductive material, including, but not limited to, metal-filled epoxies and solders, such as tin, lead/tin alloys (for example, 63% tin/37% lead solder), and high tin content alloys (e.g., 90% or more tin, such as tin/bismuth, eutectic tin/silver, ternary tin/silver/copper, eutectic tin/copper, and similar alloys). Although FIG. 1 shows integrated circuit package 200 attached to electronic substrate 110 with an interconnect-type attachment, embodiments are not so limited. For example, integrated circuit package 200 may be attached to a socket (not shown) that is electrically attached to first surface 112 of electronic substrate 110. In these and other ways, integrated circuit package 200 (and integrated circuit die 220 within it) may be connected to other integrated circuit devices, a power supply or power supplies, input/output devices, etc., for example, on or otherwise coupled to electronic substrate 110.

As further shown in FIG. 1, integrated circuit package 200 includes a porous material 260 that may be thermally coupled with second surface 224 of integrated circuit die 220, either with or without thermal interface material 254. Porous material 260 may include a parallel portion 262, having a first surface 264 and an opposing second surface 266, and one or more optional orthogonal portions 268 extending from first surface 264 of parallel portion 262 of porous material 260. Parallel portion 262 of porous material 260 may be directly on integrated circuit die 220, or directly on thermal interface material 254 on integrated circuit die 220, or both. Parallel portion 262 of porous material 260 may extend beyond a sidewall 221 of integrated circuit die 220. A border 211 in package substrate 210 extends from sidewalls 221 of integrated circuit die 220 to divide first surface 212 of package substrate 210 into a first region 213 (under integrated circuit die 220) and a second region 215 (beyond sidewalls 221 of integrated circuit die 220). Parallel portion 262 of porous material 260 may extend beyond sidewall 221 of integrated circuit die 220 over second region 215. Orthogonal portions 268 may be attached or sealed to first surface 212 of package substrate 210 with the attachment adhesive 252, which can act as a sealant layer.

Porous material 260 may be made of any appropriate thermally conductive material, including, but not limited to, at least one metal material and alloys of more than one metal, or highly doped glass or highly conductive ceramic material, such as aluminum nitride. In some embodiments, porous material 260 is or includes a ceramic or metal particles, carbon nanotubes, a metallic foam, a sintered metal pad, a metal mesh, and the like, which may further include diamond, copper, nickel, aluminum, alloys thereof, laminated metals including coated materials (such as nickel coated copper), and the like. Thermal interface material 254 may be any appropriate, thermally conductive material, including, but not limited to, a solder, a liquid metal, a mixture of liquid metal and polymer, a thermal grease, a thermal gap pad, a polymer, an epoxy filled with high thermal conductivity fillers, such as metal particles or silicon particles, and the like.

As illustrated in FIG. 1, porous material 260 may be a single material throughout, such as when porous material 260, including orthogonal portions 268, is formed by a single process operation, including but not limited to, stamping, skiving, molding, and the like. However, embodiments may also include porous material 260 made of more than one component. For example, orthogonal portions 268 may be formed separately from parallel portion 262, then attached together to form porous material 260. In some embodiments, orthogonal portions 268 may be a single “picture frame” structure surrounding integrated circuit die 220.

Attachment adhesive 252 may be any appropriate material, including, but not limited to, silicones (such as polydimethylsiloxane), epoxies, and the like. It is understood that orthogonal portions 268 not only secure porous material 260 to package substrate 210, but may also help to maintain a desired distance (e.g., bond line thickness) between first surface 264 of porous material 260 and second surface 224 of integrated circuit die 220.

Prior to the attachment of porous material 260, an electrically-insulating underfill material 242 may be disposed between integrated circuit die 220 and package substrate 210, which substantially encapsulates die-to-substrate interconnects 232. Underfill material 242 may be used to reduce mechanical stress issues that can arise from thermal expansion mismatch between package substrate 210 and integrated circuit die 220. Underfill material 242 may be an epoxy material, including, but not limited to epoxy, cyanoester, silicone, siloxane and phenolic based resins, that has sufficiently low viscosity to be wicked between integrated circuit die 220 and package substrate 210 by capillary action when introduced by an underfill material dispenser (not shown), which will be understood to those skilled in the art. Underfill material 242 may be subsequently cured (hardened), such as by heat or radiation.

As shown in FIG. 1, two-phase immersion cooling system 100 may further include a dielectric low-boiling point liquid 120 in contact with integrated circuit package 200. As illustrated, dielectric low-boiling point liquid 120 may vaporize (shown in vapor or gas state as bubbles 122) on porous material 260. Herein, dielectric low-boiling point liquid 120 may be defined to be a liquid having a boiling point lower than about 60 degrees Celsius. In some embodiments, dielectric low-boiling point liquid 120 is or includes a fluorocarbon-based fluid, such as perfluorocarbons, fluoroketones, hydrofluoroethers, and hydrofluoroolefins. In some embodiments, dielectric low-boiling point liquid 120 includes perfluorohexane. In some embodiments, dielectric low-boiling point liquid 120 includes a perfluoroalkylmorpholine, such as 2,2,3,3,5,5,6,6-octafluoro-4-(trifluoromethyl)morpholine. Porous material 260 may provide a high contact area for dielectric low-boiling point liquid 120 in a liquid state to nucleate and form vapor or gas state bubbles 122. As further shown in FIG. 1, dielectric low-boiling point liquid 120 may flow (shown by arrow 124) between electronic substrate 110 and an adjacent electronic substrate or fluid containment structure 140, as driven by a pump or bubble nucleation in vertical orientation.

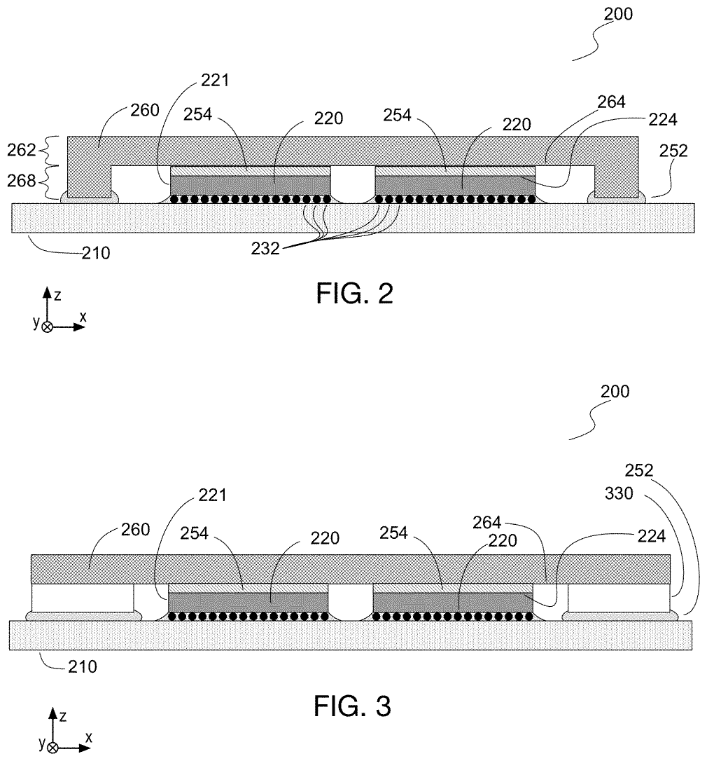

In some embodiments, areas of thermal resistance are eliminated in order to improve the performance of the two-phase immersion cooling system. It is understood that getting dielectric low-boiling point liquid 120 as close to the heat source (e.g., integrated circuit die 220) is key for heat dissipation efficiency. To this end, in some embodiments, porous material 260 is directly on integrated circuit die 220. In some embodiments, thermal interface material 254 is used to help relax interface stress and to improve the thermal contact between integrated circuit die 220 and porous material 260. As shown in FIGS. 2-5, porous material 260 of FIG. 1 is directly attached to integrated circuit dice 220, either with or without thermal interface material 254. For the purposes of the present description, the term “directly attached” is defined to mean forming porous material 260 on integrated circuit dice 220, such as by cold spraying, growth, deposition, printing, or the like, or forming porous material 260 on thermal interface material 254, such that thermal interface material 254 contacts porous material 260 and contacts integrated circuit dice 220. Porous material 260 may be a thermally conductive, high surface area structure. In some embodiments, metal powder, particles, or mesh are sintered to form porous material 260. As will be understood to those skilled in the art, sintering is a process of compacting and forming a solid mass from a powdered or particulate material by heat and/or pressure without melting the material to the point of forming a liquid. Sintering materials and processes are well known in the art and for the purposes of clarity and conciseness will not be described herein.

In some embodiments, metal or ceramic particles, including diamond, are deposited, such as by cold-spray deposition, to form porous material 260. The thickness, or z-height, of porous material 260 can be varied to best suit the conditions of a particular application. Porous material 260 can be made thinner to, e.g., minimize the distance and material between integrated circuit die 220 and the coolant, dielectric low-boiling point liquid 120, but difficulties may be encountered as porous material 260 becomes too thin. In some embodiments, the thickness of porous material 260 is as low as 500 μm. Porous material 260 can be made thicker to, e.g., meet structural requirements, but effectiveness may decrease as porous material 260 becomes too thick. In some embodiments, the thickness of porous material 260 is as high as 3 mm. For example, the thickness of porous martial 260 above integrated circuit die 220 is in the range of 500 μm to 3 mm, in some embodiments. In some embodiments, the thickness of porous martial 260 above integrated circuit die 220 is in the range of 500 μm to 1 mm. In some embodiments, the thickness of porous martial 260 above integrated circuit die 220 is in the range of 2 mm to 3 mm. Other thicknesses may be used.

In some embodiments, the porosity of porous material 260 is varied to meet system requirements or to enhance certain capabilities, e.g., heat spreading. In some embodiments, the porosity is increased, e.g., by using metal meshes with larger openings, such that porous material 260 has a porosity as high as 50%. In other embodiments, the porosity is decreased, e.g., by using finer, tighter meshes or, in a porous material formed from particles, by using mixtures of particle sizes such that the void fraction of the porous material is reduced, as will be described later herein. In some embodiments, the porosity of porous material is not more than 50%. In some embodiments, the porosity of porous material is in the range of 40% to 50%. In some embodiments, the porosity of porous material is in the range of 30% to 45%. In some embodiments, the porosity of porous material is in the range of 25% to 40%. Other porosity values may be used. As used herein, the term porosity (or void fraction) is defined according to its standard use as the fraction of volume of voids over total volume.

In some embodiments, the porosity of porous material 260 is varied with z-height to meet system requirements or to enhance certain capabilities, e.g., heat spreading. In some embodiments, the porosity increases with z-height above integrated circuit dice 220, such that there is more space for vapor bubbles 122 as dielectric low-boiling point liquid 120 vaporizes on porous material 260. A portion of porous material 260 nearer, e.g., adjacent, integrated circuit dice 220 may have a lower porosity, that is, a higher density of material and a lower void fraction, than a portion further from integrated circuit dice 220. In some embodiments, the porosity of a material portion immediately adjacent integrated circuit die 220 (e.g., on integrated circuit die 220 or on thermal interface material 254) is in the range of 25% to 35% and the porosity of a material portion distal from integrated circuit die 220 (e.g., at second surface 266) is in the range of 40% to 50%. In some embodiments, the porosity of a material portion immediately adjacent integrated circuit die 220 (e.g., on integrated circuit die 220 or on thermal interface material 254) is in the range of 15% to 30% and the porosity of a material portion distal from integrated circuit die 220 (e.g., at second surface 266) is in the range of 35% to 50%. In some embodiments, the porosity of a material portion immediately adjacent integrated circuit die 220 (e.g., on integrated circuit die 220 or on thermal interface material 254) is in the range of 10% to 20% and the porosity of a material portion distal from integrated circuit die 220 (e.g., at second surface 266) is in the range of 40% to 50%. Other porosities may be used.

FIG. 2 illustrates a cross-section view of an example integrated circuit package 200 including porous material 260 thermally coupled to and encapsulating multiple integrated circuit dice 220, arranged in accordance with at least some implementations of the present disclosure. Herein, like numerals indicate same or similar components, which may indicate similar characteristics as previously described. Although illustrated as encompassing two integrated circuit dice 220, any number may be encapsulated such as one integrated circuit die, or three, four, or more integrated circuit dice. Porous material 260 may be pre-formed (such as a sintered metal pad, a mesh of copper, and the like) and directly attached to integrated circuit dice 220 with thermal interface material 254. Mesh structures are well known in the art and for the purposes of clarity and conciseness will not be described herein. Integrated circuit dice 220 may be electrically connected to package substrate 210 by die-to-substrate interconnects 232. First surface 264 of parallel portion 262 of porous material 260 may be directly attached by way of thermal interface material 254 to second surface 224 of integrated circuit dice 220. Porous material 260 may be pre-formed and may extend beyond sidewall 221 of integrated circuit die 220 to orthogonal portions 268 that may be sealed to package substrate 210 using attachment adhesive 252, thereby encapsulating integrated circuit dice 220.

In some embodiments, porous material 260 is pre-formed in sizes, shapes, etc. to meet the needs of various embodiments, e.g., certain chip sizes or quantities. In some embodiments, effort and expense early in manufacturing can save subsequent effort and expense, e.g., later in assembly, and vice versa. For example, pre-forming, when desired, can obviate the need in some embodiments for support structures that have certain advantages in other embodiments.

FIG. 3 shows a cross-section view of another example of integrated circuit package 200, where porous material 260 is thermally coupled to multiple integrated circuit dice and attached to package substrate 210 via a frame 330, arranged in accordance with at least some implementations of the present disclosure. In this case, porous material 260 is shown on one or more frames 330, which in turn are on package substrate 210. In some embodiments, porous material 260 is pre-formed (such as a mesh of copper and the like) and directly attached to integrated circuit dice 220 with thermal interface material 254. First surface 264 of porous material 260 may be directly attached by way of thermal interface material 254 to second surface 224 of integrated circuit dice 220. Porous material 260 extends beyond sidewalls 221 of integrated circuit dice 220 to frames 330, which may be or form a single “picture frame” structure. Porous material 260 mounts on frames 330 that may in turn connect and be sealed to package substrate 210 using attachment adhesive 252, thereby encapsulating integrated circuit dice 220.

In some embodiments, the use of, e.g., frames 330 allows for easier and less costly manufacturing or for important methods of manufacture or assembly not possible (or less convenient) otherwise. In some embodiments, frame 330 is made of a metal, including but not limited to a stainless steel and a similar alloy, which can provide mechanical stiffness for the package.

In some embodiments, the forming of porous material 260 is such that the porosity of porous material 260 varies with z-height above integrated circuit dice 220, as discussed herein. For example, the porosity can be made to increase with z-height above integrated circuit dice 220, such that the portion of porous material 260 adjacent integrated circuit dice 220 may have a lower porosity than a portion further from integrated circuit dice 220. Such forming may be done, e.g., by sintering metal meshes together such that the first, lowest layer of mesh nearest integrated circuit dice 220 has smaller openings and so a relatively lower porosity and the uppermost mesh distal integrated circuit dice 220 has larger openings and so a relatively higher porosity.

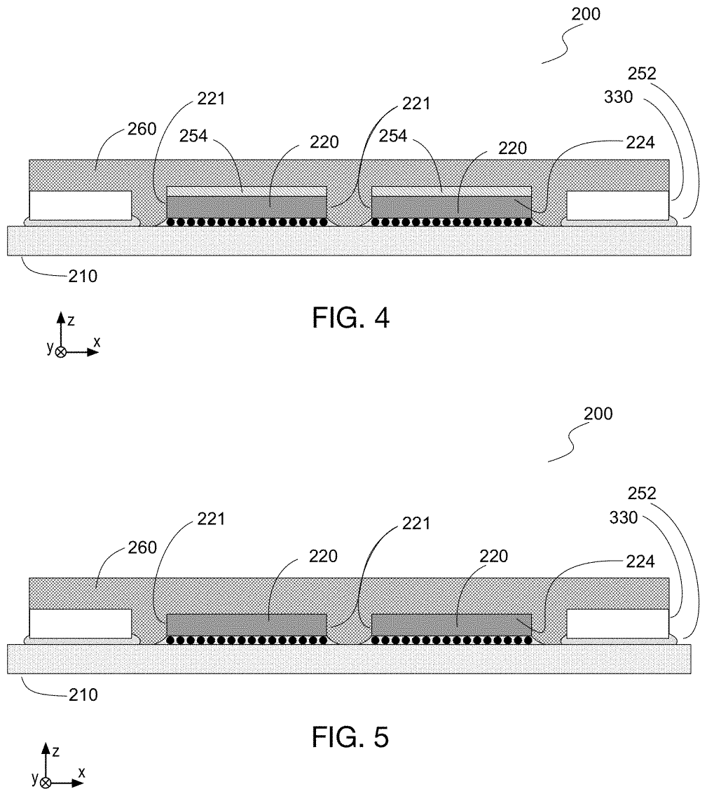

FIG. 4 illustrates a cross-section view of an example of integrated circuit package 200 having porous material 260 on thermal interface material 254 and encapsulating integrated circuit dice 220, arranged in accordance with at least some implementations of the present disclosure. For example, porous material 260 may be directly on integrated circuit dice 220 and package substrate 210 by forming porous material 260 on and beyond thermal interface material 254 and second surface 224 of integrated circuit dice 220. The forming of porous material 260 may be by cold spraying, growth, deposition, printing, or the like, such that thermal interface material 254 contacts porous material 260 and contacts integrated circuit dice 220. Additionally, the forming of porous material 260 may be such that porous material 260 contacts integrated circuit dice 220 beyond thermal interface material 254, e.g., on sidewalls 221 of integrated circuit dice 220. Porous material 260 may be formed beyond sidewalls 221 of integrated circuit dice 220 onto package substrate 210 or onto frames 330, which may be or form a single “picture frame” structure. In some embodiments, the space between integrated circuit dice 220 and frames 330 is filled entirely with porous material 260. Frames 330 may connect and be sealed to package substrate 210 using attachment adhesive 252, thereby encapsulating integrated circuit dice 220.

In some embodiments, the forming of porous material 260 is done, e.g., by cold-spray deposition of metal or ceramic particles, including diamond, using particles of substantially the same size, and the porosity is higher, approaching 50%. For example, porous material 260 could be made to have a higher porosity by cold-spray deposition of particles substantially of a single size, e.g., of a single group of particles with an average cross-sectional width of about 30 μm, where the porosity is substantially set by the predominate size and shape of the particles.

Similarly, in some embodiments, the forming by cold-spray deposition uses mixtures of particles of various sizes to give a lower porosity. Porous materials 260 with a lower porosity may be formed by cold-spray deposition of particles of varied sizes, e.g., of at least two groups of particles, one with an average cross-sectional width of about 20 μm and another with an average cross-sectional width of about 30 μm. In some embodiments, the porosity of porous material 260 is between 30 to 40%. Porous materials 260 with a lower porosity still may be formed using mixtures of particles of more varied sizes, e.g., of more groups of particles or groups with sizes chosen to fill in the voids otherwise left by larger particles. In some embodiments, porous material 260 is formed by cold-spray deposition of metal or diamond particles of average cross-sectional width of about 5 μm, 20 μm, and 30 μm, so as to have a porosity of around 20%. In this way, the porosity (or void fraction) of porous material 260 can be controlled and manipulated.

In some embodiments, the forming of porous material 260 is such that the porosity of porous material 260 may vary with z-height above integrated circuit dice 220. For example, the porosity can be made to increase with z-height above integrated circuit dice 220, such that the portion of porous material 260 adjacent integrated circuit dice 220 may have a lower porosity than a portion further from integrated circuit dice 220. Such forming may be done, e.g., by cold-spray deposition of metal or ceramic particles, including diamond. The portion of porous material 260 adjacent integrated circuit dice 220 with a lower porosity may be formed by cold-spray deposition of particles of varied sizes, e.g., of at least two groups of particles, one with an average cross-sectional width of about 20 μm and another with an average cross-sectional width of about 30 μm. The portion of porous material 260 distal integrated circuit dice 220 could be made to have a higher porosity by cold-spray deposition of particles substantially of a single size, e.g., of a single group of particles with an average cross-sectional width of about 30 μm. Similarly, other gradients or other portions of varying porosity of porous material 260 could be formed by using other mixtures of particles. Less porous layers could be formed using mixtures of particles such that smaller-sized particles could be used to partially fill voids left between larger-sized particles. In some embodiments, a lower-porosity, adjacent portion could be formed by cold-spray deposition of metal or diamond particles of more than two sizes, e.g., 5 μm, 20 μm, and 30 μm, so as to be less porous, and a higher-porosity, distal portion of porous material 260 could be formed by cold-spray deposition of metal or diamond particles of 30 μm (or 20 μm and 30 μm). In some embodiments, porous materials 260 have porosities of around 20%. In this way, the porosity of particular portions of porous material 260 can be controlled and manipulated. Less-porous layers or other portions could be formed by filling in somewhat with smaller particles the spaces between larger particles.

FIG. 5 illustrates a cross-section view of an example of integrated circuit package 200 having porous material 260 directly on and encapsulating integrated circuit dice 220, arranged in accordance with at least some implementations of the present disclosure. As shown in FIG. 5, thermal interface material 254 of FIGS. 1-4 may not be deployed in some embodiments. The cross-section view of FIG. 5 shows an example integrated circuit package 200 similar to the embodiment illustrated in FIG. 4, but without thermal interface material 254. For example, porous material 260 may be directly on integrated circuit dice 220 by forming porous material 260 on and beyond second surface 224 of integrated circuit dice 220. The forming of porous material 260 may be by cold spraying, growth, deposition, printing, or the like, such that porous material 260 contacts integrated circuit dice 220. Additionally, the forming of porous material 260 may be such that porous material 260 contacts integrated circuit dice 220 beyond second surface 224 of integrated circuit dice 220, e.g., on sidewalls 221 of integrated circuit dice 220. Porous material 260 may be formed beyond sidewalls 221 of integrated circuit dice 220 onto package substrate 210 or onto frames 330, which may be or form a single “picture frame” structure. In some embodiments, the space between integrated circuit dice 220 and frames 330 is filled entirely with porous material 260. Frames 330 may connect and be sealed to package substrate 210 using attachment adhesive 252, thereby encapsulating integrated circuit dice 220.

In some embodiments, porous material 260 is formed by cold spraying, growth, deposition, printing, or the like, such that the material composition of porous material 260 is varied with z-height above integrated circuit dice 220. The 3D buildup, growth, printing, cold-spray coating, or other deposition may be done such that some layers or other portions include different materials, or have different concentrations of materials, than other layers or other portions. For example, in some embodiments, the forming of porous material 260 can provide for a highest concentration of carbon nanotubes in the portion of porous material 260 immediately above integrated circuit die 220, and one or more lower concentrations of carbon nanotubes in one or more other portions of porous material 260 as the z-height above integrated circuit die 220 increases. Two layers of different concentrations may be one above the other, or other and more gradients of various concentrations can be arranged as suits a particular embodiment.

The embodiments of FIG. 2-5 may reduce the height of integrated circuit package 200, reduce thermal resistance, and promote boiling of dielectric low-boiling point liquid 120. Thus, the embodiments of FIGS. 2-5 may result in enhanced boiling and higher thermal performance.

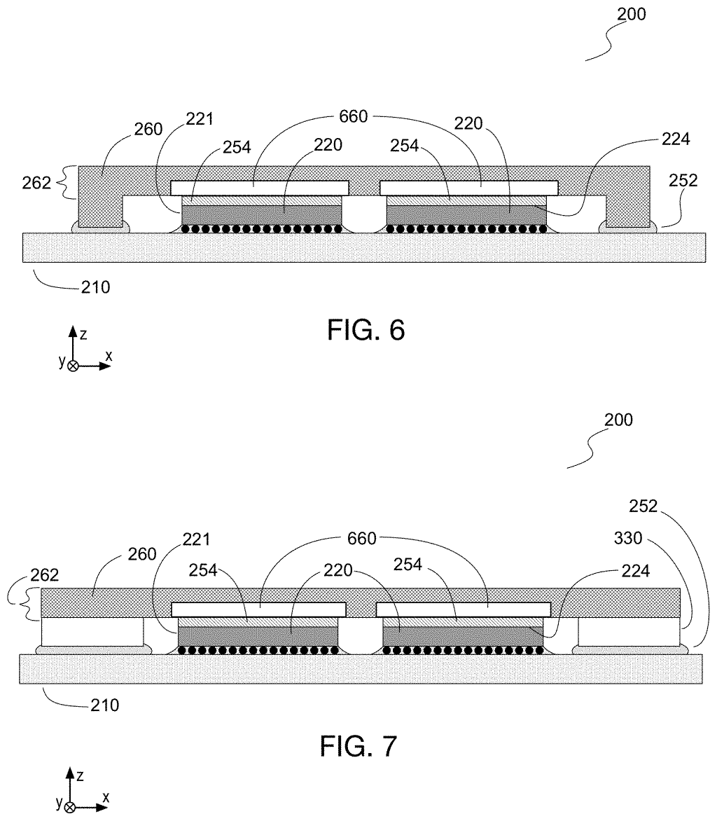

In some embodiments, further areas of thermal coupling are enhanced in order to improve the boiling and so the thermal performance. As shown in FIGS. 6-9, one or more spreader inserts 660 may be used above integrated circuit dice 220 as conditions warrant. Spreader inserts 660 may be used to spread heat generated by integrated circuit dice 220 into porous material 260. Additionally, spreader inserts 660 may aid in assembly processability during the manufacturing process, e.g., in allowing the connecting or coupling of a preferred porous material 260 to integrated circuit dice 220. In some embodiments, spreader inserts 660 are porous materials themselves and are assembled such that they can be considered part of porous material 260. Spreader inserts 660 may include copper slugs, other metals or diamond or composites of the same, vapor chambers, carbon nanotubes or composites, and the like.

FIG. 6 illustrates a cross-section view of an example integrated circuit package 200 including porous material 260 thermally coupled to integrated circuit dice 220 using spreader inserts 660, arranged in accordance with at least some implementations of the present disclosure. Porous material 260 may be pre-formed (such as a sintered metal pad, a mesh of copper, and the like) and coupled to integrated circuit dice 220 with thermal interface material 254 and spreader inserts 660. Parallel portion 262 of porous material 260 may be thermally coupled to second surface 224 of integrated circuit dice 220 by way of thermal interface material 254 and spreader inserts 660. Porous material 260 may extend beyond sidewalls 221 of integrated circuit dice 220 and may be sealed to package substrate 210 using attachment adhesive 252, thereby encapsulating integrated circuit dice 220. In some embodiments, the use of spreader inserts 660 may facilitate better thermal connection to and enable the easier assembly of porous material 260 preferred in that embodiment.

FIG. 7 shows a cross-section view of another example of integrated circuit package 200, where porous material 260 is thermally coupled to integrated circuit dice 220 via spreader inserts 660, and mechanically coupled to package substrate 210 via frames 330, arranged in accordance with at least some implementations of the present disclosure. In some embodiments, porous material 260 is pre-formed (such as a sintered metal pad, a mesh of copper, and the like) and coupled to integrated circuit dice 220 with thermal interface material 254 and spreader inserts 660. Parallel portion 262 of porous material 260 may be thermally coupled to second surface 224 of integrated circuit dice 220 by way of thermal interface material 254 and spreader inserts 660. Porous material 260 may extend beyond sidewalls 221 of integrated circuit die 220 to frames 330, which may be or form a single “picture frame” structure. In some embodiments, the space between integrated circuit dice 220 and frames 220 is filled entirely with porous material 260. Porous material 260 may be mounted on frames 330 that may in turn connect and be sealed to package substrate 210 using attachment adhesive 252, thereby encapsulating integrated circuit dice 220. In some embodiments, the use of spreader inserts 660 facilitates better thermal connection to and enables the easier assembly of porous material 260 preferred in a given embodiment.

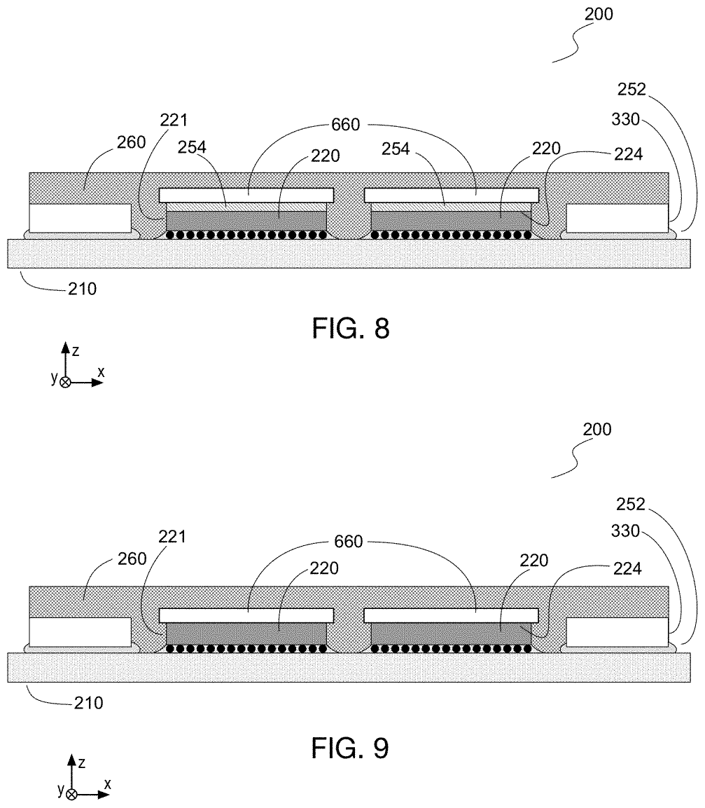

FIG. 8 illustrates a cross-section view of another example of integrated circuit package 200 where porous material 260 is coupled to integrated circuit dice 220 by forming porous material 260 on and over package substrate 210, beyond thermal interface material 254, spreader inserts 660, and second surface 224 of integrated circuit dice 220, arranged in accordance with at least some implementations of the present disclosure. The forming of porous material 260 may be by cold spraying, growth, deposition, printing, or the like, such that thermal interface material 254 contacts integrated circuit dice 220 and, through spreader inserts 660, thermally contacts porous material 260. Additionally, the forming of porous material 260 may be such that porous material 260 contacts integrated circuit dice 220 beyond thermal interface material 254 and spreader inserts 660, e.g., on sidewalls 221 of integrated circuit dice 220. Porous material 260 may be formed beyond sidewalls 221 of integrated circuit dice 220 onto package substrate 210 or onto frames 330, which may be or form a single “picture frame” structure. In some embodiments, the space between integrated circuit dice 220 and frames 330 is filled entirely with porous material 260. The frames 330 may connect and be sealed to package substrate 210 using attachment adhesive 252, thereby encapsulating integrated circuit dice 220.

FIG. 9 illustrates a cross-section view of another example of integrated circuit package 200 where porous material 260 is coupled to integrated circuit dice 220 by forming porous material 260 on spreader inserts 660 absent a thermal interface material, arranged in accordance with at least some implementations of the present disclosure. As shown in FIG. 9, thermal interface material 254 of FIGS. 6-8 may be removed. The cross-section view of FIG. 9 shows an example integrated circuit package 200 with spreader inserts 660 and without thermal interface material 254. Similar to the embodiment illustrated in FIG. 8, but without thermal interface material 254, porous material 260 may be coupled to integrated circuit dice 220 by forming porous material 260 on and beyond spreader inserts 660 and second surface 224 of integrated circuit dice 220. The forming of porous material 260 may be by cold spraying, growth, deposition, printing, or the like, such that porous material 260 contacts integrated circuit dice 220. Additionally, the forming of porous material 260 may be such that porous material 260 contacts integrated circuit dice 220 beyond second surface 224 of integrated circuit dice 220, e.g., on sidewalls 221 of integrated circuit dice 220. Porous material 260 may be formed beyond sidewalls 221 of integrated circuit dice 220 onto package substrate 210 or onto frames 330, which may be or form a single “picture frame” structure. In some embodiments, the space between integrated circuit dice 220 and frames 330 is filled entirely with porous material 260. Frames 330 may connect and be sealed to package substrate 210 using attachment adhesive 252, thereby encapsulating integrated circuit dice 220.

As with the embodiments of FIGS. 2-5, the embodiments of FIGS. 6-9 may reduce the height of integrated circuit package 200, reduce thermal resistance, and promote boiling of dielectric low-boiling point liquid 120. Thus, the embodiments of FIGS. 6-9 may result in enhanced boiling and higher thermal performance.

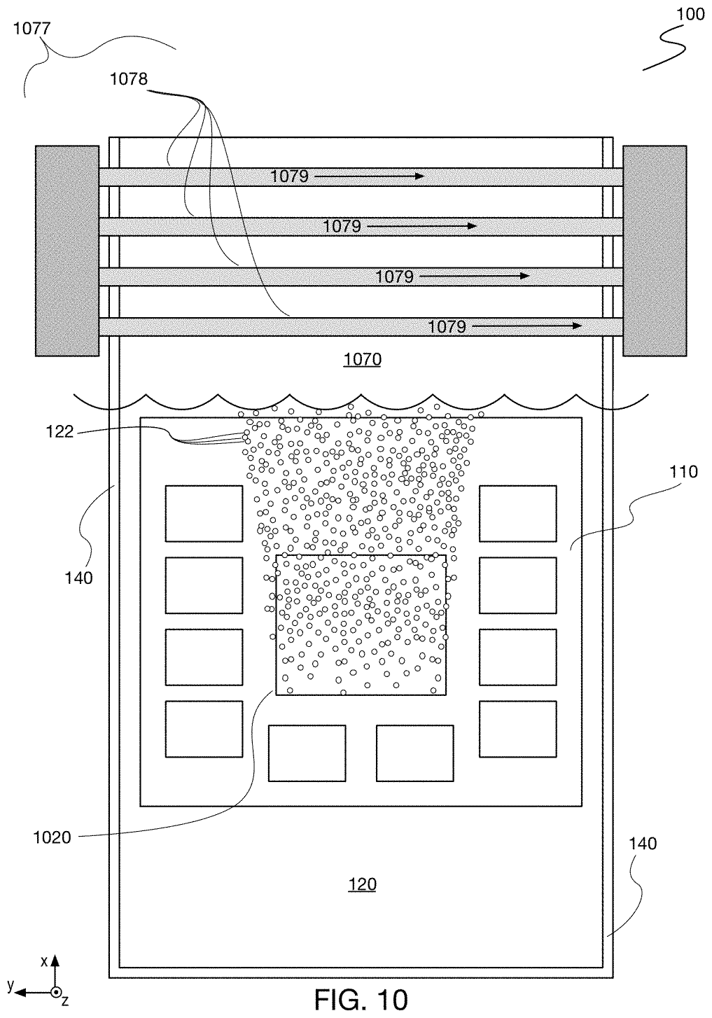

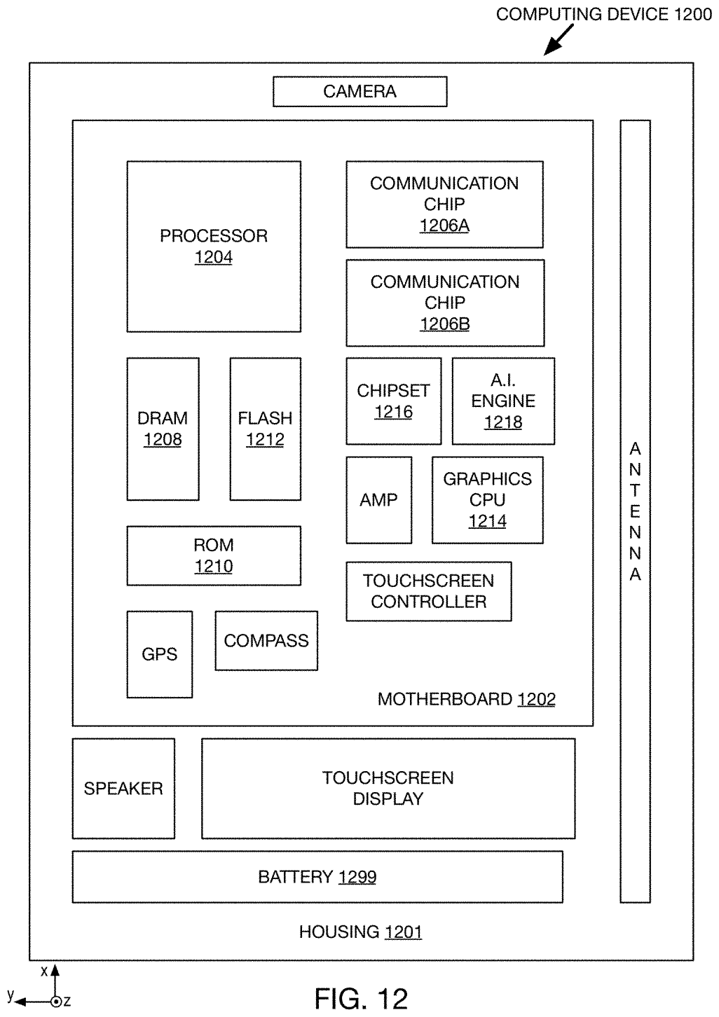

FIG. 10 shows a two-phase immersion cooling system 100 with fluid containment structure 140, dielectric low-boiling point liquid 120 disposed within fluid containment structure 140, and a condensation structure 1077 at least partially within fluid containment structure 140, arranged in accordance with at least some implementations of the present disclosure. In operation, a heat generation source 1020, such as integrated circuit packages 200 of any of FIGS. 1-9 (as well as any of the integrated circuit components of the computing device 1200 of FIG. 12) may be immersed in dielectric low-boiling point liquid 120. (Integrated circuit dice 220 within integrated circuit packages 200 of FIGS. 1-9 are understood to be the ultimate sources of heat in those respective embodiments.) Heat generation source 1020 may itself include porous material on integrated circuit dice coupled to electronic substrate 110. Electronic substrate 110 may be coupled to a power supply (not shown) and may be partially or completely submerged in dielectric low-boiling point liquid 120. The heat produced by heat generation source 1020 vaporizes dielectric low-boiling point liquid 120 (shown in vapor or gas state as bubbles 122), which may collect gravitationally above dielectric low-boiling point liquid 120 as a vapor portion 1070 within fluid containment structure 140. Condensation structure 1077 may extend through the vapor portion 1070. In some embodiments, condensation structure 1077 is a heat exchanger having a plurality of tubes 1078 with a cooling fluid (i.e., a fluid colder than the condensation point of vapor portion 1070) shown by arrows 1079 that may flow through tubes 1078 to condense vapor portion 1070 back to dielectric low-boiling point liquid 120.

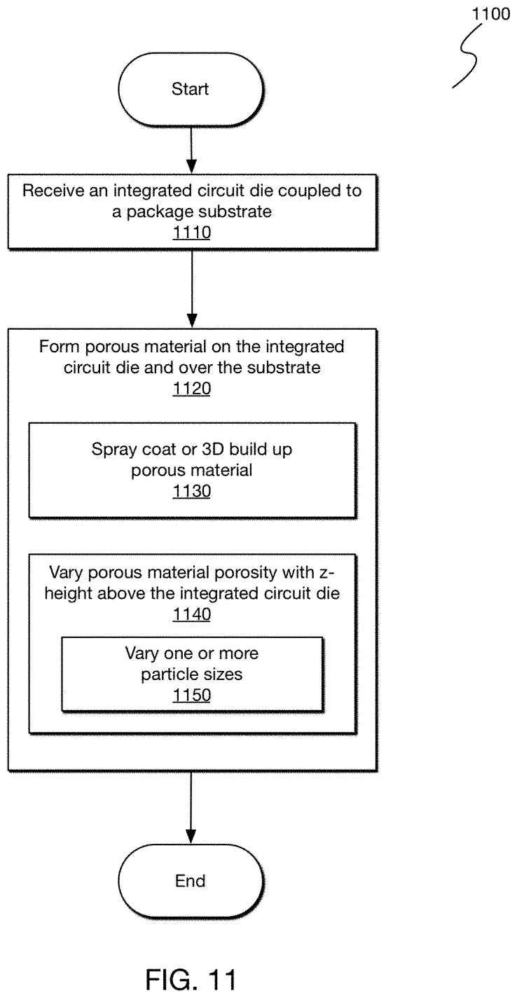

FIG. 11 illustrates various processes or methods 1100 for forming porous material on a received integrated circuit die, arranged in accordance with at least some implementations of the present disclosure. The processes include operations 1110 and 1120, and some processes include one or more optional operations 1130, 1140, and 1150. Given an integrated circuit die coupled to a package substrate, as discussed previously, a porous material can be formed directly on or formed and attached to one or more integrated circuit dice. The porous material may extend beyond the edges or sidewalls of an integrated circuit die over the substrate. This is shown in operations 1110, where an integrated circuit die, coupled to a package substrate, is received, and 1120, where a porous material is formed onto and beyond an integrated circuit die and over the package substrate. The porous material can be formed either with or without the use of thermal interface material, that is, directly on thermal interface material, or formed and attached to thermal interface material, that is in turn directly on one or more integrated circuit dice. The assembly of some porous materials may benefit from separate formation and subsequent attachment. In some embodiments, metal meshes of various fineness are separately sintered together and then attached to a received integrated circuit die. In some embodiments, metal meshes of various fineness are sintered together and onto a spreader insert, which is then attached to a received integrated circuit die.

Porous materials can be formed to various sizes to extend beyond integrated circuit die sidewalls or edges and to allow for, e.g., different integrated circuit die sizes, quantities, and configurations. In some embodiments, metal particles are sintered onto a spreader insert and then attached to a received integrated circuit die. Some porous materials are formed (e.g., with various printing, 3D buildup, growth, coating, deposition, or other methods) directly on a received integrated circuit die. Such processes allow for formation of various extents, even well beyond the edges of a single integrated circuit die to optionally include multiple dice.

In embodiments that include optional operation 1130, a cold-spray coating method may be used to form a porous material by depositing a mixture of copper and synthetic diamond particles onto and over an integrated circuit die and onto a substrate the die is coupled to. In some embodiments, cold-spray coating methods are used to deposit a mixture of particles onto a spreader insert and then another mixture onto a received integrated circuit die coupled to a substrate. In other embodiments, a 3D buildup process may be used to grow a porous material onto and over an integrated circuit die and onto a substrate the die is coupled to.

As shown in optional operation 1140, some embodiments may employ varied porosities in different portions of the porous material to, e.g., enhance boiling. In some embodiments, portions of the porous material formed nearest an integrated circuit die have less porosity and portions further from the integrated circuit die are more porous. In some embodiments, the porous material is formed by sintering metal meshes together and attaching them to an integrated circuit die and over a substrate, such that the lowest mesh adjacent the integrated circuit die is very fine and tight and not very porous, and the top mesh furthest from the integrated circuit die is more porous, having larger openings relative to the metal of the mesh. In some embodiments, a porous material is formed on an integrated circuit die and over a substrate, and a metal foam is formed on an integrated circuit die with the foam adjacent the die having relatively fewer and smaller voids than the foam furthest from the die, which has more and or larger voids and so is more porous. In some embodiments, shown in optional operation 1150, a porous material is formed on an integrated circuit die and over a substrate, and the porous material includes particles of various sizes such that a top layer of the porous material is more porous than a bottom layer of the porous material adjacent the integrated circuit die. In this embodiment, the porosities are set by the one or more sizes of the particles making up the porous material, as the top layer of the porous material is formed substantially from particles with average cross-sectional widths of 30 μm and a bottom layer of the porous material (adjacent the integrated circuit die) is formed from a mixture of particles with average cross-sectional widths of 20 μm and 30 μm. In some embodiments, a porous material with porosity of 50% forms a top layer and a porous material with porosity of 35% forms a bottom layer. The use of the relatively smaller particles in the bottom layer of the porous material will allow for the voids nearest the integrated circuit die to be filled in somewhat more than those in the top layer making for a lower porosity in the bottom layer of the porous material adjacent the integrated circuit die and a higher porosity in the top layer of the porous material. In some embodiments, the porous material in the top layer is formed with a mixture of particles with average cross-sectional widths of 20 μm and 30 μm and the porous material adjacent the integrated circuit die is formed with a mixture having even smaller particles, e.g., with average cross-sectional widths of 20 μm and 30 μm but also 1 μm and 5 μm, such that the voids nearest the integrated circuit die are generally filled in more and so are smaller than those distal the integrated circuit die. In some embodiments, a porous material with porosity of 40% forms a top layer and a porous material with porosity of 20% forms a bottom layer. In some embodiments, porous materials are made to have porosities of around 10%. In a yet further embodiment, the porous material of varying porosities is formed on the integrated circuit die and over its substrate using a cold-spray coating method of depositing the various particle mixtures.

FIG. 12 illustrates an electronic system, specifically a computing device 1200, in accordance with at least some implementations of the present disclosure. Computing device 1200 may include a housing 1201 having a board 1202 disposed therein. Computing device 1200 may include a number of integrated circuit components, including but not limited to a processor 1204, at least one communication chip 1206A, 1206B (including Network Devices or Processors), volatile memory 1208 (e.g., DRAM), non-volatile memory 1210 (e.g., ROM), flash memory 1212, a graphics processor or CPU 1214, a digital signal processor (not shown), a crypto processor (not shown), a chipset 1216, an Artificial Intelligence (A.I.) Engine 1218, an antenna, a display (touchscreen display), a touchscreen controller, a battery 1299 (or other power supply), an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to board 1202. In some implementations, at least one of the integrated circuit components may be a part of processor 1204.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

The entire computing device 1200 or at least one of the integrated circuit components within computing device 1200 may be immersed in a two-phase immersion cooling system, e.g., a fluid containment structure containing a dielectric low-boiling point liquid. In some embodiments, the integrated circuit component includes an integrated circuit package having a porous material on a thermal interface material and one or more integrated circuit dice. In some embodiments, the porous material is formed or directly attached on the integrated circuit die(s) without the use of thermal interface material.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-12. The subject matter may be applied to other integrated circuit devices and assembly applications, as well as any appropriate electronic application, as will be understood to those skilled in the art.

The following examples pertain to further embodiments, and specifics in the examples may be used anywhere in one or more embodiments.

In one or more first embodiments, an apparatus comprises an integrated circuit die coupled to a first region of a surface of a package substrate, and a porous material directly on the integrated circuit die or directly on a thermal interface material on the integrated circuit die, wherein the porous material extends beyond a sidewall surface of the integrated circuit die and over a second region of the surface of the package substrate.

In one or more second embodiments, further to the first embodiments, the porous material comprises at least one of ceramic particles or metal particles.

In one or more third embodiments, further to the first or second embodiments, a porosity of the porous material increases as a z-height increases above the integrated circuit die.

In one or more fourth embodiments, further to the first through third embodiments, the porous material comprises a first portion adjacent a top surface of the integrated circuit die and a second portion distal from the top surface of the integrated circuit die, the second portion comprising a greater porosity than the first portion, and the second portion comprising particles of a first size and the first portion comprising particles of the first size and a second size.

In one or more fifth embodiments, further to the first through fourth embodiments, the porous material comprises carbon nanotubes.

In one or more sixth embodiments, further to the first through fifth embodiments, a concentration of the carbon nanotubes in the porous material decreases as a z-height increases above the integrated circuit die.

In one or more seventh embodiments, further to the first through sixth embodiments, a second integrated circuit die is coupled to a third region of the surface of the package substrate, and a spreader insert is directly on the second integrated circuit die or directly on a thermal interface material on the second integrated circuit die, wherein the porous material is directly on the spreader insert.

In one or more eighth embodiments, further to the first through seventh embodiments, the spreader insert comprises one or more of copper, diamond, carbon nanotubes, or a vapor chamber.

In one or more ninth embodiments, further to the first through eighth embodiments, the porous material comprises a first portion substantially parallel with the package substrate and one or more second portions substantially orthogonal with, and connected to, the package substrate, wherein the integrated circuit die is enclosed by the porous material and the package substrate.

In one or more tenth embodiments, further to the first through ninth embodiments, the porous material extends substantially parallel to the package substrate and is mounted on a frame connected to the package substrate, wherein the integrated circuit die is enclosed by the package substrate, the porous material, and the frame.

In one or more eleventh embodiments, further to the first through tenth embodiments, the porous material is on the sidewall surface of the integrated circuit die and the second region of the surface of the substrate package.

In one or more twelfth embodiments, further to the first through eleventh embodiments, a second integrated circuit die is coupled to a third region of the surface of the package substrate, wherein the porous material is on the sidewall surface of the second integrated circuit die and the porous material fills that portion of the second region of the surface of the substrate package between the first integrated circuit die and the second integrated circuit die.

In one or more thirteenth embodiments, further to the first through twelfth embodiments, the porous material has a porosity of not more than 50%.

In one or more fourteenth embodiments, further to the first through thirteenth embodiments, the porous material comprises particles with average cross-sectional widths of not less than 20 μm and not more than 30 μm.

In one or more fifteenth embodiments, further to the first through fourteenth embodiments, a power supply is coupled to the package substrate.

In one or more sixteenth embodiments, a system comprises a power supply, an integrated circuit die coupled to a package substrate, and a porous material on the integrated circuit die or on a thermal interface material on the integrated circuit die, wherein the porous material is over a footprint of the integrated circuit die and extends beyond the footprint of the integrated circuit die in one or more directions parallel to the package substrate.

In one or more seventeenth embodiments, further to the sixteenth embodiments, a second integrated circuit die with a second footprint is coupled to the package substrate, and a spreader insert is on the second integrated circuit die or on a thermal interface material on the second integrated circuit die, wherein the porous material is on the spreader insert, and wherein the spreader insert comprises one or more of copper, diamond, carbon nanotubes, or a vapor chamber.

In one or more eighteenth embodiments, further to the sixteenth through seventeenth embodiments, the porous material comprises at least one of ceramic or metal particles.

In one or more nineteenth embodiments, further to the sixteenth through eighteenth embodiments, a fluid containment structure contains a dielectric low-boiling point liquid, wherein the porous material and the integrated circuit die are submerged in the dielectric low-boiling point liquid.

In one or more twentieth embodiments, a method comprises receiving an integrated circuit die coupled to a first region of a surface of a package substrate, and forming a porous material directly on the integrated circuit die or directly on a thermal interface material on the integrated circuit die, wherein the porous material extends beyond a sidewall of the integrated circuit die and over a second region of the surface of the package substrate.

In one or more twenty-first embodiments, further to the twentieth embodiments, said forming the porous material comprises forming the porous material directly on a spreader insert coupled to a second integrated circuit die on a second region of the surface of the package substrate.

In one or more twenty-second embodiments, further to the twentieth through twenty-first embodiments, a porosity of the porous material varies with z-height above the integrated circuit die.

In one or more twenty-third embodiments, further to the twentieth through twenty-second embodiments, the porous material comprises particles and the varying of the porosity of the porous material is controlled by varying one or more particle sizes of the one or more porous material particles.

In one or more twenty-fourth embodiments, further to the twentieth through twenty-third embodiments, said forming the porous material comprises cold-spray coating the porous material onto the integrated circuit die and the package substrate.

Having thus described in detail embodiments of the present invention, it is understood that the invention defined by the appended claims is not to be limited by particular details set forth in the above description, as many apparent variations thereof are possible without departing from the spirit or scope thereof.

We claim:

1. An apparatus, comprising:
an integrated circuit die coupled to a first region of a surface of a package substrate; and
a porous material directly on the integrated circuit die or directly on a thermal interface material on the integrated circuit die, wherein the porous material extends beyond a sidewall surface of the integrated circuit die and over a second region of the surface of the package substrate.

2. The apparatus of claim 1, wherein the porous material comprises at least one of ceramic particles or metal particles.

3. The apparatus of claim 1, wherein a porosity of the porous material increases as a z-height increases above the integrated circuit die.

4. The apparatus of claim 3, wherein the porous material comprises a first portion adjacent a top surface of the integrated circuit die and a second portion distal from the top surface of the integrated circuit die, the second portion comprising a greater porosity than the first portion, and the second portion comprising particles of a first size and the first portion comprising particles of the first size and a second size.

5. The apparatus of claim 1, wherein the porous material comprises carbon nanotubes.

6. The apparatus of claim 5, wherein a concentration of the carbon nanotubes in the porous material decreases as a z-height increases above the integrated circuit die.

7. The apparatus of claim 1, further comprising:
a second integrated circuit die coupled to a third region of the surface of the package substrate; and
a spreader insert directly on the second integrated circuit die or directly on a thermal interface material on the second integrated circuit die, wherein the porous material is directly on the spreader insert.

8. The apparatus of claim 7, wherein the spreader insert comprises one or more of copper, diamond, carbon nanotubes, or a vapor chamber.

9. The apparatus of claim 1, wherein the porous material comprises a first portion substantially parallel with the package substrate and one or more second portions substantially orthogonal with, and connected to, the package substrate, wherein the integrated circuit die is enclosed by the porous material and the package substrate.

10. The apparatus of claim 1, wherein the porous material extends substantially parallel to the package substrate and is mounted on a frame connected to the package substrate, wherein the integrated circuit die is enclosed by the package substrate, the porous material, and the frame.

11. The apparatus of claim 1, wherein the porous material is on the sidewall surface of the integrated circuit die and the second region of the surface of the substrate package.

12. The apparatus of claim 11, further comprising:
a second integrated circuit die coupled to a third region of the surface of the package substrate, wherein the porous material is on the sidewall surface of the second integrated circuit die and the porous material fills that portion of the second region of the surface of the substrate package between the first integrated circuit die and the second integrated circuit die.

13. The apparatus of claim 1, wherein the porous material has a porosity of not more than 50%.

14. The apparatus of claim 1, wherein the porous material comprises particles with average cross-sectional widths of not less than 20 μm and not more than 30 μm.

15. A system, comprising:
a power supply;
an integrated circuit die coupled to a package substrate; and
a porous material on the integrated circuit die or on a thermal interface material on the integrated circuit die, wherein the porous material is over a footprint of the integrated circuit die and extends beyond the footprint of the integrated circuit die in one or more directions parallel to the package substrate.

16. The system of claim 15, further comprising:
a second integrated circuit die with a second footprint coupled to the package substrate; and
a spreader insert on the second integrated circuit die or on a thermal interface material on the second integrated circuit die, wherein the porous material is on the spreader insert, and wherein the spreader insert comprises one or more of copper, diamond, carbon nanotubes, or a vapor chamber.

17. The system of claim 15, wherein the porous material comprises at least one of ceramic or metal particles.

18. The system of claim 15, further comprising:
a fluid containment structure containing a dielectric low-boiling point liquid, wherein the porous material and the integrated circuit die are submerged in the dielectric low-boiling point liquid.

19. A method, comprising:
receiving an integrated circuit die coupled to a first region of a surface of a package substrate; and
forming a porous material directly on the integrated circuit die or directly on a thermal interface material on the integrated circuit die, wherein the porous material extends beyond a sidewall of the integrated circuit die and over a second region of the surface of the package substrate.

20. The method of claim 19, wherein said forming the porous material comprises forming the porous material directly on a spreader insert coupled to a second integrated circuit die on a second region of the surface of the package substrate.

21. The method of claim 19, wherein a porosity of the porous material varies with z-height above the integrated circuit die.

22. The method of claim 21, wherein the porous material comprises particles and the varying of the porosity of the porous material is controlled by varying one or more particle sizes of the one or more porous material particles.

23. The method of claim 19, wherein said forming the porous material comprises cold-spray coating the porous material onto the integrated circuit die and the package substrate.
